(19) United States
(12) Patent Application Publication
(10) Pub. No.: US 2019/0221440 A1
(43) Pub. Date: Jul. 18, 2019

(54) Etching Method and Etching Apparatus

(71) Applicant: TOKYO ELECTRON LIMITED, Tokyo (JP)

(72) Inventors: Yasuo ASADA, Nirasaki City (JP); Takehiko ORII, Nirasaki City (JP); Kento SUZUKI, Nirasaki City (JP)

(21) Appl. No.: 16/244,511

(22) Filed: Jan. 10, 2019

(30) Foreign Application Priority Data
Jan. 17, 2018 (JP) 2018-005792

(51) Int. Cl. H01L 21/306; B08B 7/00; H01L 21/02; H01L 21/3065; H01L 21/67

(52) U.S. Cl. CPC H01L 21/30604; B08B 7/0071; H01L 21/31116; H01L 21/3065; H01L 21/67069; H01L 21/02057

(57) ABSTRACT

An etching method includes etching a silicon-containing film formed on a surface of a substrate by supplying an iodine heptafluoride gas and a basic gas to the substrate.

### CROSS-REFERENCE TO RELATED APPLICATION(S)

This application is based upon and claims the benefit of priority from Japanese Patent Application No. 2018-005792, filed on Jan. 17, 2018, the entire contents of which are incorporated herein by reference.

### TECHNICAL FIELD

The present disclosure relates to a technique of etching a silicon-containing film using an iodine heptafluoride gas.

### BACKGROUND

In a manufacturing process of a semiconductor device, a process of removing a silicon-containing film such as a polysilicon film or the like formed on a surface of the semiconductor wafer (hereinafter, referred to as a “wafer”) is often carried out. In some related arts, an iodine heptafluoride (IF₇) gas having high etching selectivity to a polysilicon film is used when etching the polysilicon film. In some related arts, for the purpose of adjusting etching performance, a gas obtained by adding an oxidizing gas or an inert gas to the IF₇ gas is used as an etching gas for etching a silicon layer.

When dry etching of a silicon-containing film is performed using an etching gas such as the IF₇ gas or the like, it is difficult to perform the etching with high in-plane uniformity of the wafer. For example, there is a case where a process is performed so as to form a recess as a pattern by etching a silicon-containing film buried in the wafer surface. In such a case, when uniformity of etching is low, a phenomenon called “footing” in which a relatively large amount of silicon-containing film remains at a bottom portion near a sidewall of the recess may occur. That is to say, orthogonality between a side surface and a bottom surface of the recess becomes low in a longitudinal sectional view, and thus it is difficult to form a recess having a good shape with high orthogonality.

Therefore, a process of removing a lower portion of the silicon-containing film by wet etching after removing an upper portion of the silicon-containing film by anisotropic etching using plasma, for example, is often carried out. However, there is a concern that plasma etching as mentioned above may cause damage to a surface of a wafer, and it takes a long time to perform multiple processes including the plasma etching and the wet etching. Therefore, there is a demand to remove the silicon-containing film by dry etching without using plasma.

However, the techniques as described above cannot solve such a problem.

### SUMMARY

Some embodiments of the present disclosure provide a technique capable of etching a silicon-containing film with high in-plane uniformity of a substrate.

According to one embodiment of the present disclosure, there is provided an etching method including etching a silicon-containing film formed on a surface of a substrate by supplying an iodine heptafluoride gas and a basic gas to the substrate.

According to one embodiment of the present disclosure, there is provided an etching apparatus including: a process container; a mounting part installed in the process container and configured to mount a substrate having a silicon-containing film formed on a surface of the substrate; and a gas supply part configured to supply an iodine heptafluoride gas and a basic gas to the process container so as to etch the silicon-containing film.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIGS. 1A to 1C are process views illustrating an etching process according to a comparative example.

FIGS. 2A to 2C are process views illustrating an etching process according to an embodiment of the present disclosure.

FIG. 3 is a plan view of a substrate processing apparatus for performing etching.

FIG. 4 is a longitudinal sectional view of an etching module installed in the substrate processing apparatus.

FIG. 5 is a longitudinal sectional view of a wafer to be processed by the substrate processing apparatus.

FIG. 6 is a longitudinal sectional view of the wafer after being processed by the substrate processing apparatus.

FIG. 7 is a schematic view illustrating a longitudinal section of a wafer according to a comparative test.

FIG. 8 is a schematic view illustrating a longitudinal section of a wafer according to a comparative test.

FIG. 9 is a graph illustrating a result of an etching amount according to an evaluation test.

FIG. 10 is a graph illustrating a result of roughness according to an evaluation test.

FIG. 11 is a graph illustrating a result of an etching amount according to an evaluation test.

FIG. 12 is a graph illustrating a result of roughness according to an evaluation test.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described with reference to detail so as not to unnecessarily obscure aspects of the various embodiments.

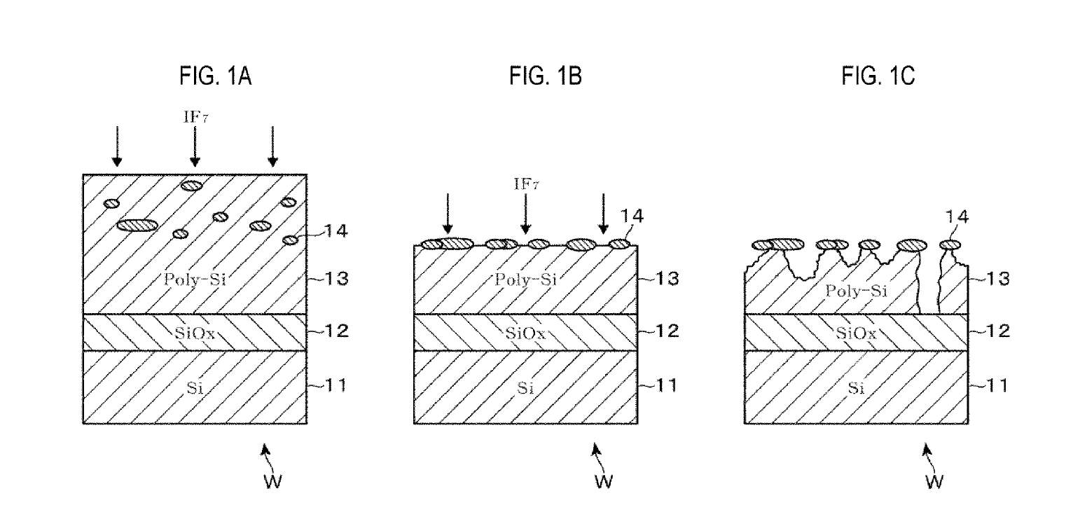

Before describing a process of the present disclosure, a process according to a comparative example will be described with reference to FIG. 1A to 1C, which is a longitudinal sectional view of a surface portion of a wafer W. As illustrated in FIG. 1A, the surface portion of the wafer W is formed by stacking a silicon (Si) layer 11, a silicon oxide film 12, and a polysilicon film 13 sequentially from bottom to top. In this process example, an IF₇ gas is supplied to the wafer W so that an upper portion of the polysilicon film 13 as a silicon-containing film is etched without exposing the silicon oxide film 12. The polysilicon film 13 contains impurities 14 formed by, e.g., silicon oxide.

Since etching selectivity of the IF₇ gas to the silicon-containing film is relatively high, an etching rate is relatively high. Thus, the polysilicon film 13 is rapidly etched downward (FIG. 1B). The impurities 14 are exposed during the progress of etching. However, since etching selectivity of the IF₇ gas to the impurities 14 is relatively low, the impurities 14 act as a mask. Therefore, in the plane of the wafer W, the etching process hardly proceeds below the impurities 14, and places where the impurities 14 do not exist continue to be rapidly etched. FIG. 1C illustrates the wafer W after the etching process is completed. Due to the existence of the impurities 14 as described above, a relatively large variation in etching amount occurs in the plane of the wafer W. It has been also confirmed that when the etching process is performed with the IF₇ gas, surface roughness of the remaining polysilicon film 13 becomes relatively large (FIG. 1C).

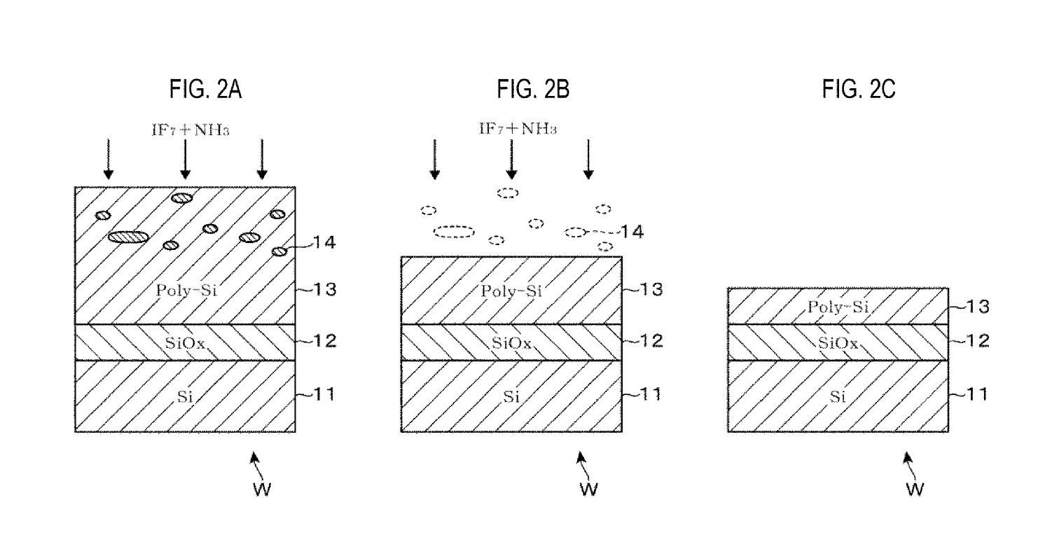

Next, an outline of a process according to an embodiment of the present disclosure and a reaction presumed to occur during the process will be described with reference to FIGS. 2A to 2C. In this process, an etching gas obtained by adding an ammonia (NH₃) gas as a basic gas to an IF₇ gas is supplied to, for example, the wafer W having the surface portion as described above (FIG. 2A). It is considered that the IF₇ gas and the NH₃ gas react with each other as indicated by the following formula (1) to generate ammonium fluoride (NH₄F), and the NH₄F becomes a deposit adhered to the surface of the wafer W.

3IF₇+aNH₃=3IF₅+bHF+cNH₄F+N₂ Formula (1)

(where a=2 to 5, b=8-a (=0 to 6), and c=a-2 (=0 to 3))

Then, the NH₄F adhered to the surface of the wafer W reacts with the impurities 14 and the impurities 14 are etched. Furthermore, since the IF₇ gas is supplied in a state where the NH₄F is adhered to the wafer W, the etching rate of the polysilicon film 13 is suppressed from becoming excessively high. Therefore, the etching process is performed so that the impurities 14 exposed to the surface of the wafer W are removed by etching and the polysilicon film 13 in a region where the impurities 14 do not exist is prevented from being rapidly etched (FIG. 2B). As will be described in detail later, the NH₄F adhered to the wafer W is sublimated and removed depending on a heating temperature of the wafer W during the etching process. FIG. 2C illustrates the wafer W after the etching process is completed. As a result of the progress of the etching process as described above, the polysilicon film 13 is etched with high in-plane uniformity of the wafer W, as illustrated in FIG. 2C. It has been also confirmed that the surface of the polysilicon film 13 is suppressed from being roughened by performing the etching process in the above-described manner.

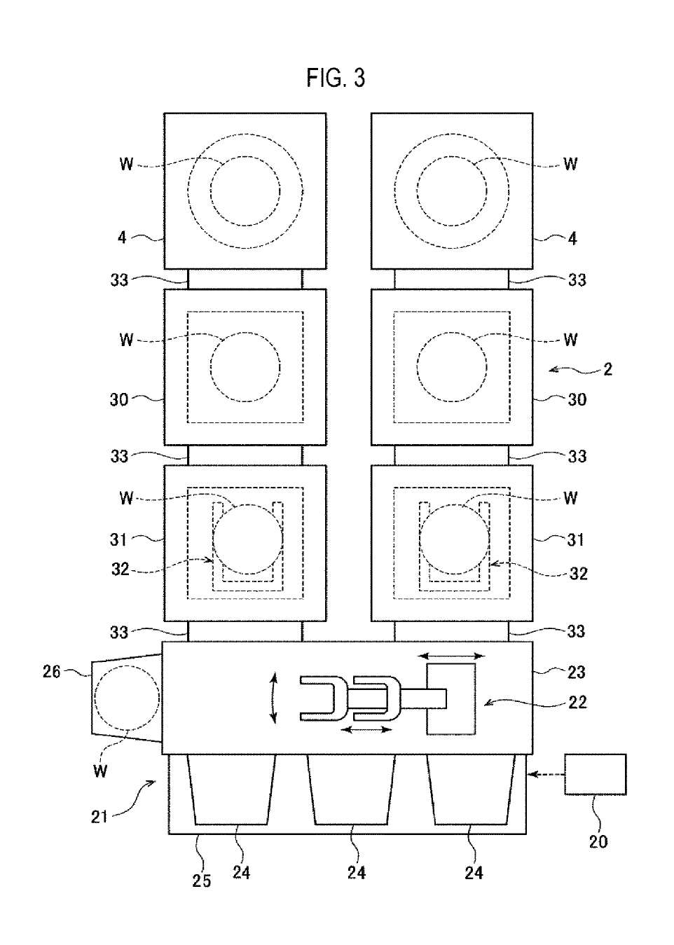

Subsequently, a substrate processing apparatus 2 including an etching module 4 for performing an etching process using the IF₇ gas and the NH₃ gas as an additive gas will be described with reference to the plan view of FIG. 3. The substrate processing apparatus 2 includes a loading/unloading part 21 for loading and unloading the wafer W, two load lock chambers 31 installed adjacent to the loading/unloading part 21, two heat treatment modules 30 respectively installed adjacent to the two load lock chambers 31, and two etching modules 4 respectively installed adjacent to the two heat treatment modules 30.

The loading/unloading part 21 includes a normal pressure transfer chamber 23 kept under a normal pressure atmosphere and a carrier loading stage 25 installed at a side portion of the normal pressure transfer chamber 23. A first substrate transfer mechanism 22 is installed in the normal pressure transfer chamber 23. Carriers 24 accommodating wafers W are loaded on the carrier loading stage 25. In FIG. 3, reference numeral 26 denotes an orienter chamber installed adjacent to the normal pressure transfer chamber 23. The orienter chamber 26 optically obtains an amount of eccentricity by rotating the wafer W and aligns the wafer W with the first substrate transfer mechanism 22. The first substrate transfer mechanism 22 transfers the wafer W among the carriers 24 on the carrier loading stage 25, the orienter chamber 26, and the load lock chambers 31.

A second substrate transfer mechanism 32 having, for example, an articulated arm structure, is installed in each of the load lock chambers 31. The second substrate transfer mechanism 32 transfers the wafer W among the load lock chambers 31, the heat treatment modules 30, and the etching modules 4. The interior of process containers constituting the heat treatment modules 30 and the etching modules 4 is kept under a vacuum atmosphere. The interior of the load lock chambers 31 is switched between the normal pressure atmosphere and the vacuum atmosphere so that the wafer W can be transferred between the process containers kept under the vacuum atmosphere and the normal pressure transfer chamber 23.

In FIG. 3, reference numeral 33 denotes gate valves that can be opened and closed. The gate valves 33 are respectively installed between the normal pressure transfer chamber 23 and the load lock chambers 31, between the load lock chambers 31 and the heat treatment modules 30, and between the heat treatment modules 30 and the etching modules 4. Each of the heat treatment modules 30 includes the process container storing the wafer W and having an interior exhausted to a vacuum atmosphere, and a loading table installed in the process container and configured to heat the wafer W loaded on the loading table. With this configuration, each of the heat treatment modules 30 performs heat treatment on the wafer W having been subjected to the etching process using the IF₇ gas and the NH₃ gas and removes etching residues adhered to the wafer W.

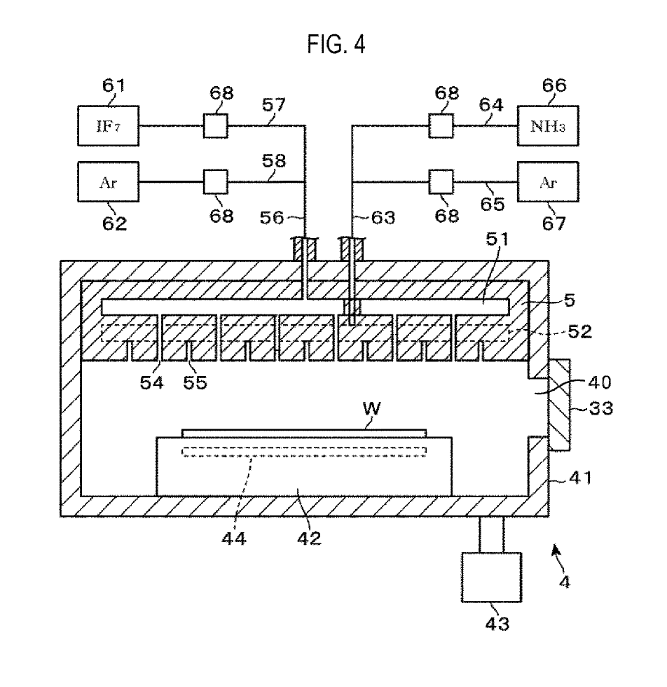

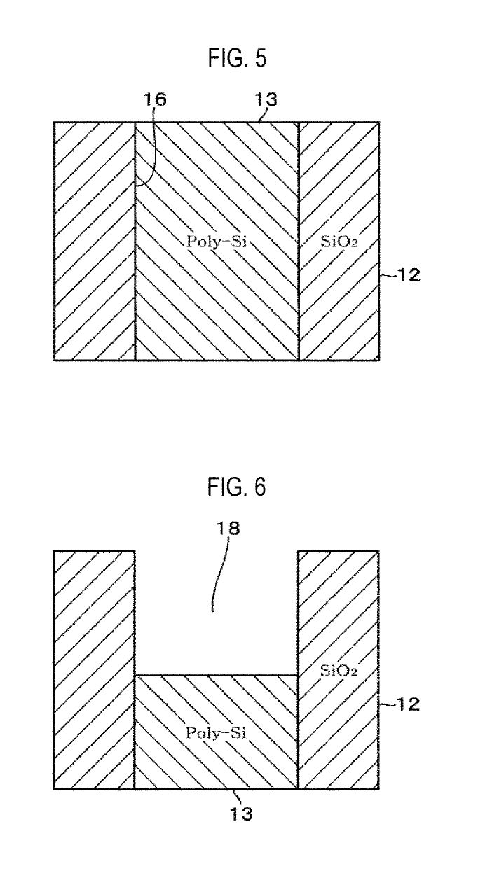

Subsequently, the etching module 4 will be described with reference to FIG. 4 which is a longitudinal sectional view. The etching module 4 includes a process container 41, a mounting table 42 arranged in the process container 41, a gas shower head 5 arranged in an upper portion of the process container 41 so as to face the mounting table 42, and an exhaust unit 43 for exhausting an interior of the process container 41 to adjust an internal pressure of the process container 41. In FIG. 4, reference numeral 40 denotes a transfer port of the wafer W formed in the process container 41. The transfer port 40 is opened and closed by a gate valve 33. The wafer W is mounted on an upper surface of the mounting table 42 in a horizontal posture. In FIG. 4, reference numeral 44 denotes a heater buried in the mounting table 42. The heater 44 heats the wafer W mounted on the mounting table 42 to a set temperature. Three lift pins having upper surfaces protrudable with respect to the upper surfaces of the mounting table 42 are installed in the mounting table 42. Thus, the wafer W can be delivered between the mounting table 42 and the second substrate transfer mechanism 32. In FIG. 4, illustration of the lift pins are omitted.

The gas shower head 5, which is a gas supply part, is configured as a horizontal plate-like body. Flat diffusion spaces 51 and 52 are respectively formed in an upper portion and a lower portion of the gas shower head 5. These diffusion spaces 51 and 52 are partitioned from each other. A plurality of respective gas discharge holes 54 and 55 which are partitioned from each other are opened to a lower surface of the gas shower head 5. The gas discharge holes 54 are in communication with the diffusion space 51 and the gas discharge holes 55 are in communication with the diffusion space 52.

A downstream end of a gas flow path 56 is connected to an upper portion of the diffusion space 51. An upstream side of the gas flow path 56 is branched to form gas flow paths 57 and 58. Upstream sides of the gas flow paths 57 and 58 are respectively connected to an IF₇ gas supply source 61 and an argon (Ar) gas supply source 62. A downstream end of a gas flow path 63 partitioned with respect to the gas flow path 56 is connected to an upper portion of the diffusion space 52. An upstream side of the gas flow path 63 is branched to form gas flow paths 64 and 65. Upstream sides of the gas flow paths 64 and 65 are respectively connected to an NH₃ gas supply source 66 and an Ar gas supply source 67. Flow rate adjustment parts 68 configured by valves and mass flow controllers are respectively interposed in the gas flow paths 57, 58, 64, and 65. The flow rate adjustment parts 68 perform supply and stop of gases with respect to downstream sides of the flow paths 57, 58, 64, and 65 and adjustment of flow rates of the gases to the downstream sides of the flow paths 57, 58, 64, and 65. The Ar gas is a dilution gas for diluting the IF₇ gas and the NH₃ gas in the process container 41. By configuring the etching module 4 as described above, the IF₇ gas and the NH₃ gas supplied from the gas supply sources 61 and 66 are not mixed with each other until the IF₇ gas and the NH₃ gas are discharged from the gas shower head 5. The IF₇ gas and the NH₃ gas are mixed with each other in the process container 41 after being discharged from the gas shower head 5.

As illustrated in FIG. 3, the substrate processing apparatus 2 further includes a controller 20 as a computer. The controller 20 includes a program, a memory, and a CPU. The program has instructions (steps) incorporated in the program so that the processing of the wafer W and the transfer of the wafer W as described above are performed. The program is stored in a computer storage medium, for example, a compact disc, a hard disk, a magneto-optical disk, a DVD, or the like, and is installed in the controller 20. The controller 20 controls each part of the substrate processing apparatus 2 by outputting a control signal to each part of the substrate processing apparatus 2 according to the program. Specifically, operation of the etching module 4, the heat treatment module 30, the first and second substrate transfer mechanism 22 and 32, and the orienter chamber 26 are controlled by the control signal. The operation of the etching module 4 includes adjustment of output of the heater 44, adjustment of the flow rate of each gas and the supply and stop of each gas by each of the flow rate adjustment parts 68, adjustment of an exhaust flow rate by the exhaust unit 43, and the like. The controller 20 and the etching module 4 constitute an etching apparatus of the present disclosure.

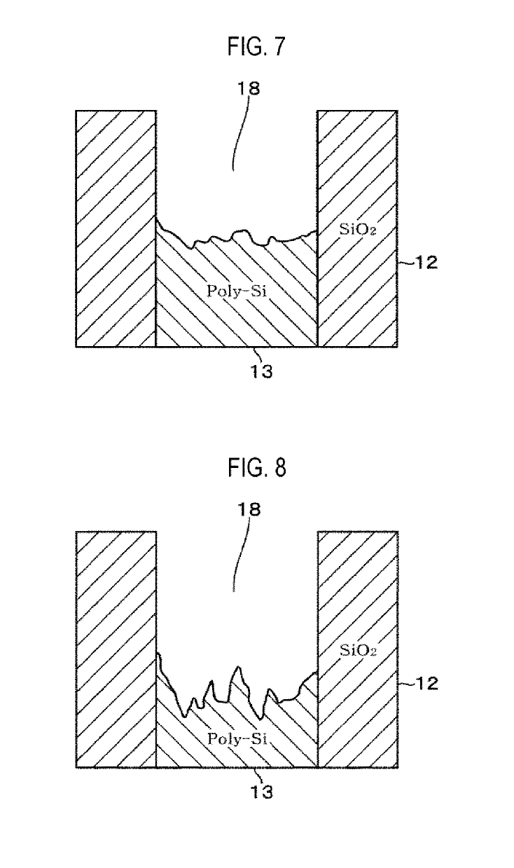

Processing of the wafer W in the substrate processing apparatus 2 will be described. Here, processing the wafer W illustrated in FIG. 5 will be described as a process example. The silicon oxide film 12 is formed on the surface of the wafer W. A through hole 16 is formed in the silicon oxide film 12, and a polysilicon film 13 is buried in the through hole 16. In this process example, an upper portion of the polysilicon film 13 is etched.

The carrier 24 storing the wafer W described with reference to FIG. 5 is loaded on the carrier loading stage 25. The wafer W is transferred in the order of the normal pressure transfer chamber 23→the orienter chamber 26→the normal pressure transfer chamber 23→the load lock chamber 31, and is then transferred to the process container 41 of the etching module 4 via the heat treatment module 30. Then, the wafer W is mounted on the mounting table 42 and heated to, e.g., 80 degrees C. The internal pressure of the process container 41, namely a pressure around the wafer W, is set to be, e.g., 13.3 Pa (100 mTorr) to 66.6 Pa (500 mTorr). The reason for setting the internal pressure of the process container 41 to be such a relatively low pressure is, as described above, to suppress an excessive increase in etching rate of the polysilicon film 13 as a silicon-containing film by the IF₇ gas.

Subsequently, the IF₇ gas, the NH₃ gas, and the Ar gas are supplied from the gas shower head 5 to the process container 41. As described with reference to FIG. 2, the IF₇ gas and the NH₃ gas react with each other to generate NH₄F, and the NH₄F adheres to the wafer W. The wafer W is heated to 80 degrees C., and at this temperature, the NH₄F gas adhered to the wafer W is sublimated. In a state where the NH₄F adhered to the surface of the wafer W is sublimated in this manner, the polysilicon film 13 is etched by the IF₇ gas. By the etching, a recess 18 is formed on the surface of the wafer W and a depth of the recess 18 gradually increases.

Even if the polysilicon film 13 contains the impurities 14 made of silicon oxide described with reference to FIG. 2, the impurities 14 are removed by the NH₄F adhered to the wafer W. Further, excessive increase in the etching rate of the polysilicon film 13 is suppressed by the NH₄F. As a result, like the case of etching the polysilicon film 13 described with reference to FIG. 2, the polysilicon film 13 is etched with high in-plane uniformity of the wafer W. Although it is considered that the NH₄F also acts on the silicon oxide film 12 in addition to the impurities 14, it has been confirmed that appearance of the silicon oxide film 12 hardly changes (there is no film loss) by experiments as conducted. It is considered that the impurities 14 are sufficiently removed by the NH₄F because an amount of the impurities 14 contained in the film is very small.

Thereafter, after a lapse of a predetermined period of time from starting the supply of the IF₇ gas, the NH₃ gas, and the Ar gas, the supply of these respective gases from the gas shower head 5 is stopped, and the etching process is completed. FIG. 6 illustrates the wafer W when the etching process is completed. As the etching process is performed as described above, the recess 18 has uniformity in depth in the plane of the wafer W. In addition, the polysilicon film 13 forming a bottom surface of the recess 18 is suppressed from being roughened. Therefore, in the recess 18, occurrence of footing as described above is suppressed. When the etching process is completed, the wafer W is transferred to the heat treatment module 30. Thus, the wafer W is subjected to heat treatment so as to reach a predetermined temperature and the etching residues are removed. Thereafter, the wafer W is transferred in the order of the load lock chamber 31→the normal pressure transfer chamber 23, and is returned to the carrier 24.

According to the substrate processing apparatus 2 including the etching module 4, it is possible to etch the polysilicon film 13 with high in-plane uniformity of the wafer W, and to suppress the surface of the polysilicon film 13 remaining after the etching process from being roughened. In addition, according to the aforementioned process, since it is not necessary to use plasma, each film on the surface of the wafer W is not damaged by plasma. Thus, there is also an advantage that reliability of a semiconductor device formed from the wafer W can be improved. However, cases where the etching process is performed using plasma are also included in the scope of the present disclosure. Although the substrate processing apparatus 2 has been described above with reference to an example of processing the wafer W illustrated in FIG. 5, the substrate processing apparatus 2 may also applied to a case of processing the wafer W illustrated in FIG. 2A. Therefore, the substrate processing apparatus 2 is not limited to being applied to a case of etching a silicon-containing film buried in a hole or a recess.

In each process example as described above, only the upper portion of the polysilicon film 13 is etched. However, the entirety of the polysilicon film 13 formed on the surface of the wafer W may be etched. In that case, since uniformity in etching rate of the polysilicon film 13 in the plane of the wafer W is high, it is possible to reduce the time required for etching. More specifically, when variation in etching rate in the plane of the wafer W is large, there is a possibility that, even though one region in the plane of the wafer W has been completely etched, another region having a low etching rate has not yet been completely etched. Therefore, in order to etch all regions in the plane of the polysilicon film 13, an etching time period is set such that the etching process continues to be performed even after one region has been etched. That is to say, the etching time is set such that the one region is subjected to overetching. However, when the uniformity in etching rate is high, a time period of overetching can be shortened or eliminated. Thus, it is possible to reduce the time required for etching as described above.

In the process example of etching the polysilicon film 13, the IF₇ gas and the NH₃ gas are simultaneously supplied to the process container 41. That is to say, a period for supplying the IF₇ gas and a period for supplying the NH₃ gas overlap so as to coincide with each other. However, the IF₇ gas and the NH₃ gas may not be supplied as such. First, only the NH₃ gas among the IF₇ gas and the NH₃ gas is supplied to the process container 41 and adsorbed to the wafer W. After the supply of the NH₃ gas is stopped, only the IF₇ gas among the IF₇ gas and the NH₃ gas is supplied to the wafer W and reacted with the NH₃ gas adsorbed to the wafer W to generate NH₄F. Thus, the impurities 14 are removed, and the polysilicon film 13 is etched by the IF₇ gas. That is to say, the process may be performed by sequentially supplying the NH₃ gas and the IF₇ gas in this order. This sequential gas supply may be repeatedly performed. That is to say, after sequentially supplying the NH₃ gas and the IF₇ gas, the NH₃ gas and the IF₇ gas may be sequentially supplied again in this order. In this manner, the NH₃ gas is not necessarily supplied to the wafer W as an additive gas to the IF₇ gas. In addition, for example, after the simultaneous supply of the IF₇ gas and the NH₃ gas to the wafer W starts, the supply of the NH₃ gas may be first stopped before the supply of the IF₇ gas is stopped. That is to say, the overlapping of the period of supplying the IF₇ gas and the period of supplying the NH₃ gas is not limited to the case where these periods coincide with each other.

The silicon-containing film is a film containing silicon as a main component, and is not limited to the polysilicon film. Specifically, the silicon-containing film may include, for example, an amorphous silicon film, a single crystal silicon film, a SiGe film, a SiC film, and the like. It is considered that a basic gas may be supplied to the wafer W in addition to the IF₇ gas, as long as the basic gas reacts with the IF₇ gas and generates a compound containing nitrogen and fluorine like the NH₄F and having an etching action on oxide. Thus, a basic gas other than the NH₃ gas may be used. Specifically, the basic gas may include hydrazine (N₂H₄) and (CH₃) methylamine (NH₂), butylamine, dimethylamine, and the like, which are amine.

In the etching module 4 described above, it may be configured such that the IF₇ gas and the NH₃ gas are supplied to, for example, a common diffusion space in the gas shower head 5. Specifically, the gas shower head 5 may be configured such that the IF₇ gas and the NH₃ gas are mixed in the gas shower head 5 and this mixed gas is discharged to the wafer W. In the etching module 4 described above, for example, it may be configured such that a gas supply part having gas discharge holes concentrically opened along a circumference of the wafer W in a plan view is installed, instead of the gas shower head 5, to supply a gas to the wafer W. That is to say, the gas supply part is not limited to the gas shower head. The present disclosure is not limited to the examples described above and examples to be described with reference to evaluation tests below, and the respective examples may be appropriately changed or combined with each other.

### (Evaluation Tests)

Evaluation tests conducted according to the present disclosure will be described.

### Evaluation Test 1

In evaluation test 1, the polysilicon film 13 was etched by simultaneously supplying an IF₇ gas, an NH₃ gas, and an Ar gas to the wafer W having the structure described with reference to FIG. 5 using the etching apparatus configured substantially similarly to the etching module 4 described with reference to FIG. 4. Then, after the etching process, an image of a longitudinal section of the wafer W was acquired using a transmission electron microscope (TEM). The flow rate of the IF₇ gas was set to be 20 to 500 sccm, the flow rate of the NH₃ gas was set to be 10 to 500 sccm, and the flow rate of the Ar gas was set to be 100 to 1,000 sccm. The supply time period of these gases, i.e., the etching time period, was set to be 3 seconds, the internal pressure of the process container 41 was set to be 6.66 to 199.9 Pa (50 to 1,500 mTorr), and the temperature of the wafer W was set to be 20 to 100 degrees C.

Furthermore, comparative tests 1-1 and 1-2, in each of which the polysilicon film 13 on the wafer W having the structure described with reference to FIG. 5 was etched and an image of the longitudinal section of the wafer W after the etching process was acquired in the same manner as evaluation test 1, were conducted under the processing conditions different from those of evaluation test 1. In comparative test 1-1, the etching process was performed by simultaneously supplying a fluorine (F₂) gas at 200 to 1,000 sccm, an NH₃ gas at 5 to 100 sccm, and an N₂ gas at 50 to 1,000 sccm to the process container 41. These respective gases are intermittently supplied to the process container 41 seven times, and after an N-th (where N is an integer) supply is performed and before an (N+1)th supply is performed, the interior of the process container 41 was purged with a purge gas. The supply time period of the F₂ gas, the NH₃ gas, and the N₂ gas at one time was set to be 30 seconds. The internal pressure of the process container 41 was set to be 13.33 to 333.3 Pa (100 to 2,500 mTorr), and the temperature of the wafer W was set to be 30 to 120 degrees C. In comparative test 1-2, the etching process was performed by simultaneously supplying a fluorine trichloride (ClF₃) gas at 50 to 500 sccm and an N₂ gas at 100 to 1,500 sccm to the process container 41. The number of times of supply of these gases to the process container 41 was once as in evaluation test 1 and the gas supply time was set to be 36.3 seconds. The internal pressure of the process container 41 was set to be 13.33 to 333.3 Pa (100 to 2,500 mTorr) and the temperature of the wafer W was set to be 30 to 120 degrees C.

In evaluation test 1, flatness in the surface of the polysilicon film 13 after the etching process forming the bottom of the recess 18 was high and thus no footing was observed. Therefore, it was confirmed that the etching process was performed with high uniformity in each portion in the plane of the wafer W. The depth of the recess 18, i.e., the etching amount, was 50 nm. FIG. 6 described above is a schematic view of a TEM image acquired in evaluation test 1. FIG. 7 is a schematic view of a TEM image obtained from comparative test 1-1 and FIG. 8 is a schematic view of a TEM image obtained from comparative test 1-2. As illustrated in FIGS. 7 and 8, flatness in the surface of the polysilicon film 13 in comparative tests 1-1 and 1-2 was lower than that in evaluation test 1, and thus footing was observed. The etching amount was 30 nm in comparative test 1-1 and 36.3 nm in comparative test 1-2. Therefore, the etching rate was larger in evaluation test 1 than in comparative tests 1-1 and 1-2. From the result of evaluation test 1, it was observed that by using the IF₇ gas and the NH₃ gas, the polysilicon film 13 can be etched with high uniformity in the plane of the wafer W while suppressing the polysilicon film 13 after the etching process from being roughened, and obtaining the high etching rate.

In evaluation test 1, the flow rate ratio of the NH₃ gas to the IF₇ gas (=the NH₃ gas flow rate/IF₇ gas flow rate) was 0.6. The temperature of the wafer W was set to be 20 to 100 degrees C. and the internal pressure of the process container 41 was set to be 6.66 to 199.9 Pa (50 to 1,500 mTorr). Therefore, it was confirmed that, by setting the flow rate ratio, the temperature of the wafer W, and the internal pressure of the process container 41 as described above, it is possible to perform the etching process with high uniformity in the plane of the wafer W, and to obtain the high etching rate as described above. In addition, the present inventors also conducted the same test as in evaluation test 1 by setting the internal pressure of the process container 41 to be a value other than 26.6 Pa. It was confirmed that a good shape of the recess 18, similarly to the result of evaluation test 1, can be obtained when the internal pressure of the process container 41 was set to be within a range of 13.3 Pa (100 mTorr) to 133.3 Pa (1,000 mTorr). Therefore, it is desirable to set the internal pressure of the process container 41 to be 13.3 Pa to 133.3 Pa.

### Evaluation Test 2

In evaluation test 2-1, an amorphous silicon film having a film thickness of 200 nm was formed on the surface of the wafer W, and then was etched by simultaneously supplying an IF₇ gas and an NH₃ gas for eight seconds using an etching apparatus configured substantially similarly to the etching module 4 described with reference to FIG. 4. As in evaluation test 1, the internal pressure of the process container 41 was set to be 50 to 1,500 mTorr. After the etching process, an image of the surface of the amorphous silicon film remaining on the wafer W was acquired, and the etching amount of the amorphous silicon film (200 nm—a film thickness of the remaining amorphous silicon film) and surface roughness of the amorphous silicon film remaining on the wafer W. Among the processing conditions, combination of the flow rate of the NH₃ gas and the temperature of the surface of the mounting table 42 (=the temperature of the wafer W) was changed for each processing. The flow rate ratio of the NH₃ gas/IF₇ gas (=the NH₃ gas flow rate/IF₇ gas flow rate) was set to be 0.2, 0.4, 0.6, 1.2, and 1.8, and the temperature of the wafer W was set to be 35 degrees C., 60 degrees C., 80 degrees C., 100 degrees C., and 120 degrees C. The flow rate of the IF₇ gas was set to be 20 to 500 sccm. The surface roughness of the amorphous silicon film prior to the etching process was 2.53 nm. The smaller roughness value indicates the higher flatness.

In evaluation test 2-2, a test similar to evaluation test 2-1 was conducted except that a polysilicon film, instead of the amorphous silicon film, was formed on the surface of the wafer W and then was etched. Then, the etching amount of the polysilicon film (200 nm—the thickness of the remaining polysilicon film) and surface roughness of the polysilicon film were measured. The roughness of the polysilicon film prior to the etching process is 7.46 nm.

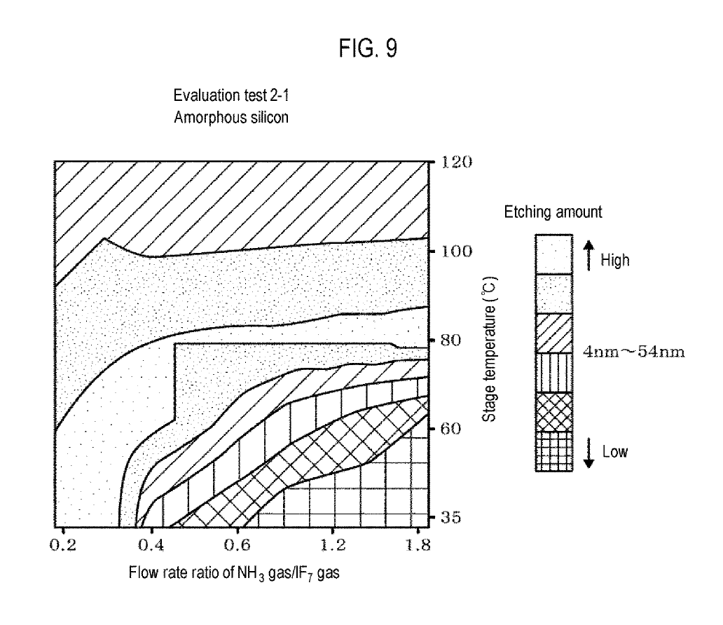

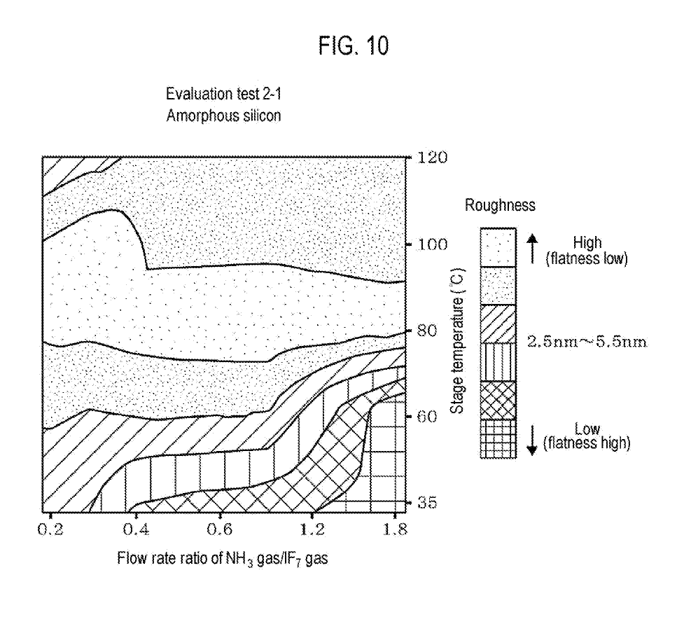

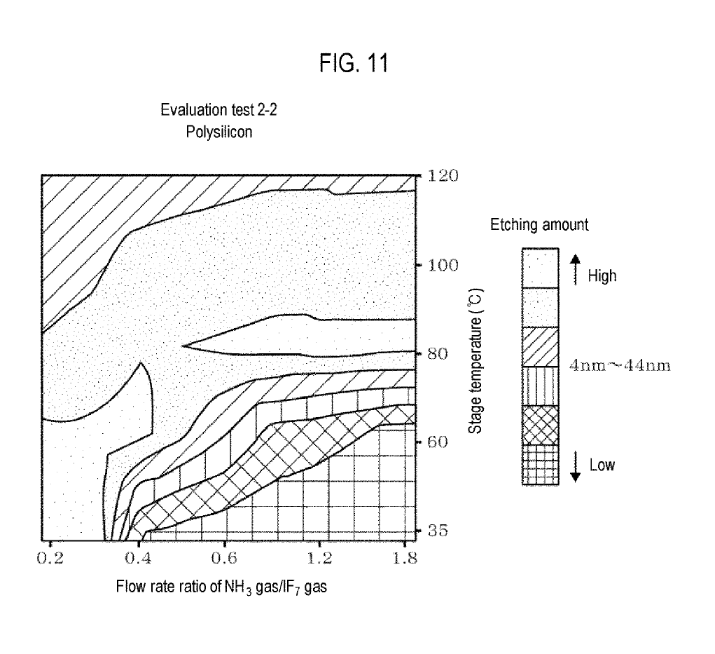

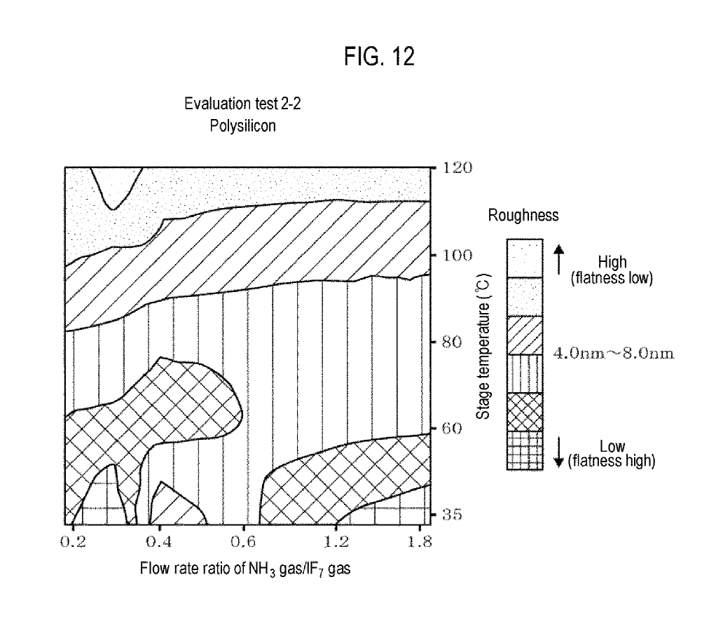

Graphs of FIGS. 9 and 10 show results of evaluation test 2-1, and graphs of FIGS. 11 and 12 show results of evaluation test 2-2. The vertical axis of each graph in FIGS. 9 to 12 indicates a temperature of a stage on which the wafer W is mounted (=a temperature of the wafer W). The horizontal axis of each graph in FIGS. 9 to 12 indicates a flow rate ratio of the NH₃ gas/IF₇ gas. The graphs of FIGS. 9 and 11 show results of etching amount. Specifically, in the graphs, contour lines are drawn to surround regions where etching amounts approximate each other and to partition regions where the etching amounts are relatively separated from each other. The regions surrounded by the contour lines are differently hatched to distinguish the respective regions from one another.

The graphs of FIGS. 10 and 12 show results of roughness. Specifically, in the graphs, contour lines are drawn to surround regions where roughness values approximate each other and to partition regions where the roughness values are relatively separated from each other. Similar to the graphs of FIGS. 9 and 11, the regions surrounded by the contour lines are differently hatched to distinguish the respective regions from one another. The graphs of FIGS. 9 to 12 are shown as described above for the convenience of illustration, although FIGS. 9 to 12 actually show distributions of the etching amount or the roughness by color gradation using computer graphics. Since the contour lines in FIGS. 9 to 12 are converted from color gradation images, FIGS. 9 to 12 show the distributions of the etching amount or the roughness more roughly than those in the actual images obtained by evaluation tests 2-1 and 2-2.

For the etching amount, a value within a range of approximately 4 to 54 nm was obtained in evaluation test 2-1, and a value within a range of approximately 4 to 44 nm was obtained in evaluation test 2-2. For the roughness, a value within a range of approximately 2.5 to 5.5 nm was obtained in the evaluation test 2-1, and a value within the range of approximately 4.0 to 8.0 nm was obtained in the evaluation test 2-2. Therefore, in evaluation tests 2-1 and 2-2, the values of the surface roughness in the amorphous silicon film and the polysilicon film remaining after the etching process do not significantly increase compared with the roughness values prior to the etching process. Thus, it was confirmed from the result of this evaluation test 2 that, by supplying the IF₇ gas and the NH₃ gas under the temperature of the wafer W set to be 35 to 120 degrees C., the effect of the present disclosure, i.e., the etching process with high in-plane uniformity of the wafer W, is obtained. Further, when the temperature of the wafer W was 35 degrees C., the roughness value was 4.2 nm or less in evaluation test 2-1 and 7.2 nm or less in evaluation test 2-2. That is to say, the surface roughness was relatively suppressed from being increased from the roughness value prior to the etching process. It is considered that the roughness value does not significantly vary even if the temperature of the wafer W is slightly lower than 35 degrees C. Thus, it is estimated that when the temperature of the wafer W is, for example, 30 to 120 degrees C., the effect of increasing the etching uniformity as described above is obtained.

As illustrated in FIG. 9, in evaluation test 2-1, when the temperature of the wafer W was 35 degrees C. or 60 degrees C. and the flow rate ratio of the NH₃ gas/IF₇ gas was relatively large, the etching amount was relatively small. However, when the temperature of the wafer W was 80 degrees C. or higher, the etching amount was a relatively large value, specifically, 30 nm or more, regardless of the flow rate ratio of the NH₃ gas/IF₇ gas. As illustrated in FIG. 10, the roughness was relatively low, specifically, 5.6 nm or less, regardless of the temperature of the wafer W and the flow rate ratio of the NH₃ gas/IF₇ gas.

As illustrated in FIG. 11, in evaluation test 2-2, when the temperature of the wafer W was 35 degrees C. or 60 degrees C. and the flow rate ratio of the NH₃ gas/IF₇ gas was relatively large, the etching amount was relatively small. However, when the temperature of the wafer W was 80 degrees C. or higher, the etching amount was a relatively large value, specifically, 29 nm or more, regardless of the flow rate ratio of the NH₃ gas/IF₇ gas. When the flow rate ratio of NH₃ gas/IF₇ gas was 0.2, 0.6, 1.2, or 1.8, the etching amount was larger when the temperature of the wafer W was set to be 100 degrees C. than when the temperature of the wafer W was set to be 120 degrees C. Therefore, it was confirmed that the etching amount is larger when the temperature of the wafer W is set to be 100 degrees C. rather than set to be 120 degrees C. As is apparent from FIG. 12, the roughness was relatively low, specifically, 9 nm or less, regardless of the temperature of the wafer W and the flow rate ratio of the NH₃ gas/IF₇ gas. From the results of evaluation tests 2-1 and 2-2, it was confirmed that, for the amorphous silicon film and the polysilicon film, in order to obtain a high etching rate and suppress surface roughness from being increased after the etching process, it is more desirable to set the temperature of the wafer W during the etching process to be 80 to 100 degrees C.

In evaluation test 2-1, comparing the case where the temperature of the wafer W was 80 degrees C. and the case where the temperature of the wafer W was 100 degrees C., when the flow rate ratio of the NH₃ gas/IF₇ gas was the same, the etching amount was larger in the case where the temperature of the wafer W was 80 degrees C. In addition, when the flow rate ratio of the NH₃ gas/IF₇ gas was 0.2 and 0.4, the roughness value was smaller in the case where the temperature of the wafer W was 80 degrees C. In evaluation test 2-2, comparing the case where the temperature of the wafer W was 80 degrees C. and the case where the temperature of the wafer W was 100 degrees C., when the flow rate ratio of the NH₃ gas/IF₇ gas was the same, the etching amount was larger and the roughness value was smaller in the case where the temperature of the wafer W was 80 degrees C. Among the temperatures of the wafer W set in evaluation test 2 as described above, 80 degrees C. was the most preferable value from the viewpoint of increasing the etching rate and suppressing the increase in roughness after etching. In the above, it has been described that, according to the processing conditions, differences in etching mount and roughness occurred between the wafer W having the temperature of 80 degrees C. and the wafer W having the temperature of 100 degrees C. However, as described above, FIGS. 9 to 12 show the test results in a rough manner. Thus, even if differences in etching amount and roughness occurred between the wafer W having the temperature of 80 degrees C. and the wafer W having the temperature of 100 degrees C., FIGS. 9 to 12 may not show the differences in some processing conditions.

The internal pressure of the process container 41 during the etching process was set as described above. Thus, the NH₄F was sublimated from the wafer W when the temperature of the wafer W was 80 degrees C. or higher. It is considered that the reason why the etching amount was relatively large when the temperature of the wafer W was 80 degrees C. or higher in evaluation tests 2-1 and 2-2 is that, even if the NH₄F is adhered, the NH₄F is sublimated and the etching action of the IF₇ gas is not largely hindered by the NH₄F. The probability that the NH₃ gas and NH₄F adsorb to the wafer W increases as the temperature of the wafer W decreases. Therefore, when the temperature of the wafer W is too high during the etching process, the action of the NH₄F becomes weak. For such a reason, it is presumed that the case where the temperature of the wafer W was 100 degrees C. shows a preferable result than the case where the temperature of the wafer W was 120 degrees C., and the case where the temperature of the wafer W was 80 degrees C. shows a more preferable result. Even at temperatures slightly varying from 80 degrees C., it is considered that the etching rate is high and the roughness is low. Considering that it is possible to sublimate the NH₄F when the temperature of the wafer W is 80 degrees C. or higher as described above, it is considered that a particularly preferable temperature range of the wafer W is 80 degrees C. or higher and lower than 100 degrees C., specifically, 80 to 90 degrees C.

According to the result when the temperature of the wafer W was 35 degrees C. or 60 degrees C. in evaluation test 2-1, the etching amount was relatively small when the flow rate of the NH₃ gas was larger than the flow rate of the IF₇ gas, namely when the flow rate ratio of the NH₃ gas/IF₇ gas was 1.2 and 1.8. However, when the flow rate of the NH₃ gas was smaller than the flow rate of the IF₇ gas, namely when the flow rate ratio of the NH₃ gas/IF₇ gas is 0.2 to 0.6, the etching amount was relatively large, except for the case where the temperature of the wafer W was 35 degrees C. and the flow rate ratio of the NH₃ gas/IF₇ gas was 0.6.

In evaluation test 2-2, according to the result when the temperature of the wafer W was 35 degrees C. or 60 degrees C., when the flow rate ratio of the NH₃ gas/IF₇ gas was 1.2 and 1.8, the etching amount was relatively small. When the flow rate ratio of NH₃ gas/IF₇ gas was 0.2 to 0.6, the etching amount was a relatively large, except for the case where the temperature of the wafer W was 35 degrees C. and the flow rate ratio of NH₃ gas/IF₇ gas was 0.6.

It is considered that the reason for these results is that the temperature at which the NH₄F is sublimated from the wafer W is 80 degrees C. or higher as described above, and in the case of 35 degrees C. and 60 degrees C. at which the sublimation does not occur, an excessive amount of NH₄F is adhered to the wafer W when the flow rate of the NH₃ gas is relatively large, so that the etching amount by the IF₇ gas is reduced. Therefore, from the result of evaluation test 2, it was confirmed that when the temperature of the wafer W is lower than 80 degrees C., it is desirable to set the flow rate ratio of NH₃ gas/IF₇ gas to be 0.6 or less.

In evaluation tests 2-1 and 2-2, when the temperature of the wafer W was set to be 80 degrees C. or higher, the roughness value did not significantly vary depending on the flow rate ratio of the NH₃ gas/IF₇ gas. However, the etching amount was larger when the flow rate ratio of NH₃ gas/IF₇ gas was set to 1.2 or 1.8 than when the flow rate ratio of NH₃ gas/IF₇ gas was set to 0.6. Therefore, it was confirmed that in the case where the temperature of the wafer W is 80 degrees C. or higher, when the flow rate ratio of the NH₃ gas/IF₇ gas is 1.2 to 1.8, it is possible to obtain a high etching rate and to significantly suppress roughness after the etching process from being increased. That is to say, it was confirmed that it is desirable to set the flow rate of the NH₃ gas/the flow rate of the IF₇ gas to be within a range of 1.2 to 1.8.

It is considered that when the temperature of the wafer W is 80 degrees C. or higher, the etching action does not vary greatly even if the flow rate ratio of the NH₃ gas/IF₇ gas is slightly smaller than 1.2. It is also considered that when the temperature of the wafer W is lower than 80 degrees C., the etching action does not vary greatly even if the flow rate ratio of the NH₃ gas/IF₇ gas is slightly larger than 0.6. Specifically, it is considered that the variation of the etching action is small, when the flow rate ratio of the NH₃ gas/IF₇ gas is, for example, 1 or more in the case where the temperature of the wafer W is 80 degrees C. or higher, and when the flow rate ratio of the NH₃ gas/IF₇ gas is, for example, 1 or less in the case where the temperature of the wafer W is lower than 80 degrees C. Therefore, it is estimated that when the temperature of the wafer W is 80 degrees C. or higher, the flow rate ratio of the NH₃ gas/IF₇ gas is preferably 1 to 1.8, and when the temperature of the wafer W is lower than 80 degrees C., the flow rate of the NH₃ gas/IF₇ gas is preferably 1 or less.

According to the present disclosure in some embodiments, it is possible to etch a silicon-containing film with high in-plane uniformity of a substrate by supplying an iodine heptafluoride gas and a basic gas to the substrate having a silicon-containing film formed on a surface of the substrate.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. An etching method, comprising:
etching a silicon-containing film formed on a surface of a substrate by supplying an iodine heptafluoride gas and a basic gas to the substrate.

2. The method of claim 1, wherein a time period during which the iodine heptafluoride gas is supplied to the substrate and a time period during which the basic gas is supplied to the substrate overlap with each other.

3. The method of claim 2, further comprising, in a state where a temperature of the substrate is set to be 80 degrees C. or higher, supplying the basic gas and the iodine heptafluoride gas to a process container that stores the substrate so that a ratio of a flow rate of the basic gas/a flow rate of the iodine heptafluoride gas becomes 1 to 1.8.

4. The method of claim 2, further comprising, in a state where a temperature of the substrate is set to be lower than 80 degrees C., supplying the basic gas and the iodine heptafluoride gas to a process container that stores the substrate so that a ratio of a flow rate of the basic gas/a flow rate of the iodine heptafluoride gas becomes 1 or less.

5. The method of claim 1, wherein the basic gas and the iodine heptafluoride gas are supplied to the substrate in this order.

6. The method of claim 1, wherein the etching the silicon-containing film includes supplying the iodine heptafluoride gas and the basic gas to the substrate in a state where a temperature of the substrate is set to be 30 to 120 degrees C.

7. The method of claim 1, wherein the etching the silicon-containing film includes supplying the iodine heptafluoride gas and the basic gas in a state where an internal pressure of a process container that stores the substrate is set to be 13.3 Pa to 133.3 Pa.

8. The method of claim 1, wherein the basic gas is an ammonia gas.

9. An etching apparatus, comprising:
a process container;
a mounting part installed in the process container and configured to mount a substrate having a silicon-containing film formed on a surface of the substrate; and
a gas supply part configured to supply an iodine heptafluoride gas and a basic gas to the process container so as to etch the silicon-containing film.
